(19) United States
(12) Patent Application Publication
(10) Pub. No.: US 2026/0271397 A1
(43) Pub. Date: Sep. 10, 2026

(54) STACKED TRANSISTOR GATE-TO-GATE CONTACT

(71) Applicant: International Business Machines Corporation, Armonk, NY (US)

(72) Inventors: Chen Zhang, Santa Clara, CA (US); Shay Reboh, Guilderland, NY (US); Ruilong Xie, Niskayuna, NY (US); Shahrukh Khan, Sandy Hook, CT (US); Tenko Yamashita, Schenectady, NY (US)

(21) Appl. No.: 19/069,446

(22) Filed: Mar. 4, 2025

(51) Int. Cl. H10D 84/85; H10D 84/01

(52) U.S. Cl. CPC H10D 84/856; H10D 84/0186; H10D 84/851

(57) ABSTRACT

Embodiments of the present disclosure relate to fabrication methods and resulting semiconductor integrated circuit (IC) devices that include a stacked transistor that has a gate-to-gate contact within bonding layer(s) that connects the top transistor to the bottom transistor. A high-κ layer that is associated with the top gate may be selectively deposited such that the high-κ layer is absent from the gate-to-gate contact. This enables the gate-to-gate contact to electrically contact a relatively higher conductivity material(s) (e.g., work function metal, or the like) within the top gate, which reduces the impedance or interfacial resistance between top gate and the gate-to-gate contact.

### BACKGROUND

A stacked transistor may include a top transistor stacked upon a bottom transistor. It may be difficult to efficiently and easily connect a top gate that is a part of the top transistor to a bottom gate that is a part of the bottom transistor.

### SUMMARY

In an embodiment of the disclosure, a semiconductor integrated circuit (IC) device is presented. The semiconductor IC device includes

[symbol]

In an embodiment of the disclosure, a semiconductor IC device is presented. The semiconductor IC device

[symbol]

In another embodiment of the present disclosure, a semiconductor IC device fabrication method is presented. The method includes

[symbol]

The above summary is not intended to describe each illustrated embodiment or every implementation or example of the present disclosure.

### BRIEF DESCRIPTION OF THE DRAWINGS

The drawings included in the disclosure are incorporated into, and form part of, the specification. They illustrate embodiments of the present disclosure and, along with the description, explain the principles of the disclosure. The drawings are only illustrative of certain embodiments and do not limit the disclosure.

FIG. 1 depicts a cross-section view of a semiconductor IC device that includes a gate-to-gate contact, according to one or more embodiments of the disclosure.

FIG. 2 depicts a partial top-down view of a semiconductor IC device that includes a gate-to-gate contact, according to one or more embodiments of the disclosure.

FIG. 3 through FIG. 12 depict various fabrication structure cross-section views of an illustrative semiconductor IC device that includes a gate-to-gate contact, according to one or more embodiments of the disclosure.

FIG. 13 depicts a method of fabricating a semiconductor IC device that includes a locally displaced top transistor active area, according to one or more embodiments of the disclosure.

### DETAILED DESCRIPTION

Embodiments of the present disclosure relate to fabrication methods and resulting semiconductor integrated circuit (IC) devices that include a stacked transistor that has a gate-to-gate contact within bonding layer(s) that connects the top transistor to the bottom transistor. A high-κ layer that is associated with the top gate may be selectively deposited such that the high-κ layer is absent from the gate-to-gate contact. This enables the gate-to-gate contact to directly contact a relatively higher conductivity material(s) (e.g., work function metal, or the like) within the top gate, which reduces the impedance or interfacial resistance between top gate and the bottom gate.

A transistor is a type of microdevice that may be fabricated in semiconductor IC device front-end-of-line (FEOL) fabrication operations. Conventional transistors, or the like, incorporate planar field effect transistors (FETs) in which current flows through a semiconducting channel between a source and a drain, in response to a voltage applied to a control gate. The semiconductor industry strives to obey Moore's law, which holds that each successive generation of integrated circuit devices shrinks to half its size and operates twice as fast. As device dimensions have shrunk, however, conventional silicon device geometries and materials have had trouble maintaining switching speeds without incurring failures such as, for example, leaking current from the device into the semiconductor substrate. Several new technologies emerged that allowed chip designers to continue shrinking transistor sizes. A FET generally is a transistor in which output current, i.e., source-drain current, is controlled by a voltage applied to an associated gate. A FET typically has three terminals, i.e., a gate structure, a source region, and a drain region. A gate structure is a structure used to control output current (i.e., flow of carriers in the channel) of a semiconducting device through electrical or magnetic fields. A channel is the region of the FET underlying the gate structure and between the source and drain of the semiconductor IC device that becomes conductive when the semiconductor device is turned on. The source is a doped region in the semiconductor IC device, in which majority carriers are flowing into the channel. A drain is a doped region in the semiconductor IC device located at the end of the channel, in which carriers are flowing out of the transistor through the drain.

One technology change modified the structure of the FET from a planar device to a three-dimensional device in which the semiconducting channel was replaced by a fin that extends out from the plane of the substrate. In such a device, commonly referred to as a FinFET, the control gate wraps around three sides of the fin to influence current flow from three surfaces instead of one. The improved control achieved with a 3D design results in faster switching performance and reduced current leakage. Building taller devices has also permitted increasing the device density within the same footprint that had previously been occupied by a planar FET.

The FinFET concept was further extended by developing a gate all-around FET, or GAA FET, in which the gate fully wraps around one or more channels for maximum control of the current flow therein. In the GAA FET, the channels can take the form of nanolayers, nanosheets, or the like, that are isolated from the substrate. In the GAA FET, channel surfaces are in respective contact with the source and drain and other respective channel surfaces are in contact with and surrounded by the gate.

The flowcharts and cross-sectional diagrams in the drawings illustrate a method of fabricating semiconductor IC device, such as a processor, FPGA, memory module, or the like. In some alternative implementations, the fabrication steps may occur in a different order than that which is noted in the drawings, and certain additional fabrication steps may be implemented between the steps noted in the drawings. Moreover, any of the layered structures depicted in the drawings may contain multiple sublayers.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” if the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “top,” “lower,” “right,” “left,” “vertical,” “horizontal,” “top,” “bottom,” and derivatives thereof shall relate to the depicted structure(s) as oriented. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

The terms “about,” “substantially,” “approximately,” and variations thereof, are intended to include the degree of error associated with measurement of the particular quantity based upon the equipment available at the time of filing the application. For example, substantial coplanarity between various materials can include an appropriate manufacturing tolerance of ±8%, ±5%, ±2%, or the like, difference between the coplanar materials.

As used herein, the term “coplanar” refers to two surfaces that lie in a common plane. In other words, two surfaces are coplanar if there exists a geometric plane that contains all the points of both of the surfaces. Accordingly, two surfaces may be referred to as substantially coplanar despite deviations from coplanarity, so long as those deviations do not impact the desired result of the coplanarity.

As used herein, the terms “selective” or “selectively” in reference to a material removal or etch process denote that the rate of material removal for a first material is greater than the rate of removal for at least another material of the structure to which the material removal process is applied. For example, in certain embodiments, a selective etch may include an etch chemistry that removes a first material selectively to a second material by a ratio of 2:1 or greater, e.g., 5:1, 10:1 or 20:1.

For the sake of brevity, conventional techniques related to semiconductor IC device fabrication may or may not be described in detail herein. Moreover, the various tasks and process steps described herein can be incorporated into a more comprehensive procedure or process having additional steps or functionality not described in detail herein. Various steps in the manufacture of semiconductor devices are well known and so, in the interest of brevity, many conventional steps will only be mentioned briefly herein or will be omitted entirely without providing the well-known process details.

In general, the various processes used to form a semiconductor IC device that may be packaged into an IC package fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

Turning now to an overview of technologies that are more specifically relevant to aspects of the present disclosure, a metal-oxide-semiconductor field-effect transistor (MOSFET) may be used for amplifying or switching electronic signals. The MOSFET has a source electrode, a drain electrode, and a metal oxide gate electrode. The metal gate portion of the metal oxide gate electrode is electrically insulated from the main semiconductor n-channel or p-channel by a thin layer of insulating material, for example, silicon dioxide or glass, which makes the input resistance of the MOSFET relatively high. The gate voltage controls whether the current path from the source to the drain is an open circuit (“off”) or a resistive path (“on”). N-type field effect transistors (nFET) and p-type field effect transistors (pFET) are two types of complementary MOSFETs. The nFET includes n-doped source and drain junctions and uses electrons as the current carriers. The pFET includes p-doped source and drain junctions and uses holes as the current carriers. Complementary metal oxide semiconductor (CMOS) is a technology that uses complementary and symmetrical pairs of p-type and n-type MOSFETs to implement logic functions. As mentioned above, hole mobility on the pFET may have an impact on overall device performance.

The wafer footprint of a FET is related to the electrical conductivity of the channel material. If the channel material has a relatively high conductivity, the FET can be made with a correspondingly smaller wafer footprint. A method of increasing channel conductivity and decreasing FET size is to form the channel as a nanostructure, such as a nano wire, nano ribbon, nanolayer, nanosheet, or the like, hereinafter referred to as a nanolayer. For example, a GAA FET provides a relatively small FET footprint by forming the channel region as a series of vertically stacked nanolayers. In a GAA configuration, a GAA FET includes a source region, a drain region and vertically stacked nanolayer channels between the source and drain regions. These devices typically include one or more suspended nanolayers that serve as the channel. A gate surrounds the stacked nanolayers and regulates electron flow through the nanolayers between the source and drain regions. GAA FETs may be fabricated by forming alternating layers of active nanolayers and sacrificial nanolayers. The sacrificial nanolayers are released from the active nanolayers before the FET device is finalized. For n-type FETs, the active nanolayers are typically silicon (Si) and the sacrificial nanolayers are typically silicon germanium (SiGe). For p-type FETs, the active nanolayers can be SiGe and the sacrificial nanolayers can be Si. In some implementations, the active nanolayers of a p-type FET can be SiGe or Si, and the sacrificial nanolayers can be Si or SiGe. Forming the nanolayers from alternating layers of active nanolayers formed from a first type of semiconductor material (e.g., Si for n-type FETs, and SiGe for p-type FETs) and sacrificial nanolayers formed from a second type of semiconductor material (e.g., SiGe for n-type FETs, and Si for p-type FETs) may provide for superior channel electrostatics control, which is necessary for continuously scaling gate lengths. Integration of multiple transistors, such as a bottom transistor and a top transistor, into a stacked configuration may allow for continued device scaling. However, there are many fabrication challenges in order to form stacked transistors at scale.

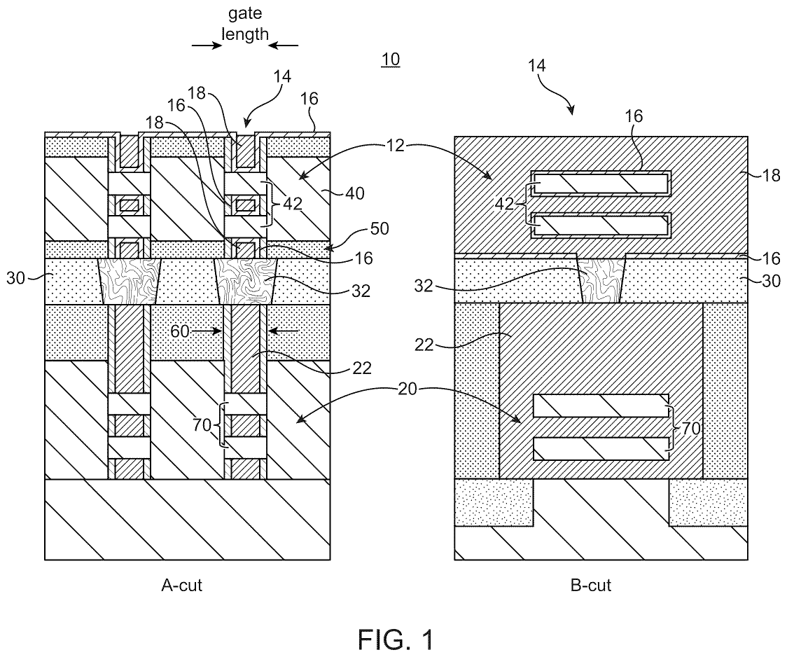

Please refer to FIG. 1, that depicts a cross-section view of a semiconductor IC device 10. In an embodiment, semiconductor IC device 10 includes a top transistor 12 that has a top gate 14. The top gate 14 at least includes a high-κ layer 16 and a gate conductor 18. In the embodiment, the semiconductor IC device 10 further includes a bottom transistor 20 comprising a bottom gate 22. In the embodiment, semiconductor IC device 10 further includes a bonding layer 30 that connects the top transistor 12 to the bottom transistor 20. In the embodiment, the semiconductor IC device 10 further includes a gate-to-gate contact 32 within the bonding layer 30 that electrically connects the gate conductor 18 to the bottom gate 22.

In an example, the bonding layer 30 is directly connected to the high-κ layer 16 and to the bottom gate 22. In an example, the top transistor 12 includes a top source/drain (S/D) region 40 and a plurality of channels 42 directly connected to the top S/D region 40 and directly connected to the high-κ layer 16.

In an example, semiconductor IC device 10 further includes a dielectric spacer 50 between the gate-to-gate contact 32 and the top S/D region 40. In an example, the dielectric spacer 50 is directly connected to the bonding layer 30, directly connected to the gate-to-gate contact 32, and directly connected to the top S/D region 40.

In an example, the gate-to-gate contact 32 is laterally inset and below the plurality of channels 42. For example, as shown in the B-cut view, the gate-to-gate contact 32 is entirely laterally located between opposing sidewalls of the plurality of channels 42. In an example, the gate-to-gate contact 32 is partially inset and below the plurality of channels 42. For example, with reference to the B-cut view, the gate-to-gate contact 32 may be directly below one set of sidewalls of the plurality of channels 42. In an example, the gate-to-gate contact 32 is laterally located outside and below the plurality of channels 42.

In an example, the gate-to-gate contact 32 has a horizontal length 60 that is greater than a gate length of the top gate 14 and a gate length of the bottom gate 22. In an example, a top surface of the dielectric spacer 50 is below a bottom surface of a bottommost channel of the plurality of channels 42.

In another embodiment of the disclosure, another semiconductor IC device 10 is presented. In the embodiment, the semiconductor IC device 10 includes the bonding layer 30 and the gate-to-gate contact 32 within the bonding layer 30. The gate-to-gate contact 32 extends from a top surface of a bonding layer 30 to a bottom surface of the bonding layer 30. In the embodiment, the semiconductor IC device 10 includes the top gate 14 that has the high-κ layer 16 that is directly connected to the bonding layer 30 and the gate conductor 18 that is directly connected to the gate-to-gate contact 32.

In an example, the semiconductor IC device 10 further includes the bottom gate 20 that is electrically connected to the gate-to-gate contact 32. In example, the high-κ layer 16 of the top gate 14 wraps around a plurality of top channels 42 and wherein the bottom gate 22 wraps around the plurality of bottom channels 70. In the example, the gate-to-gate contact 32 is laterally inset and above the plurality of bottom channels 70. In the example, the gate-to-gate contact 32 is partially inset and above the plurality of top channels 70.

In an example, the semiconductor IC device 10 further includes the top S/D region 40 directly connected to the plurality of top channels and the dielectric spacer 50 directly between the gate-to-gate contact 32 and the top S/D region 40. In an example, the dielectric spacer 50 is in direct contact with the bonding layer 30.

In an example, the semiconductor IC device 10 may be fabricated by a method that includes forming the bottom transistor 20 that includes the bottom gate 22, forming the bonding layer 30 upon the bottom transistor 20, forming the gate-to-gate contact 32 within the bonding layer 30 and in direct contact with the bottom gate 22, and forming the high-κ layer 16 of the top gate 14 upon the bonding layer 30 without being substantially formed upon the gate-to-gate contact 32.

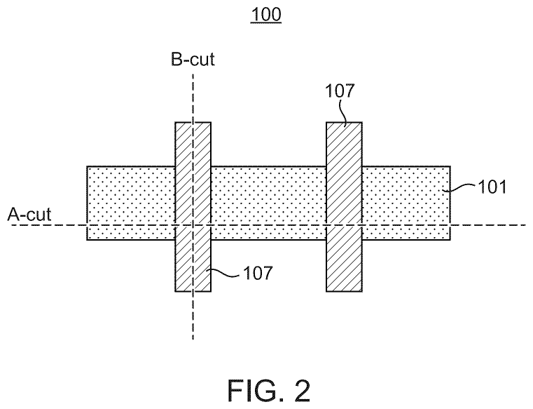

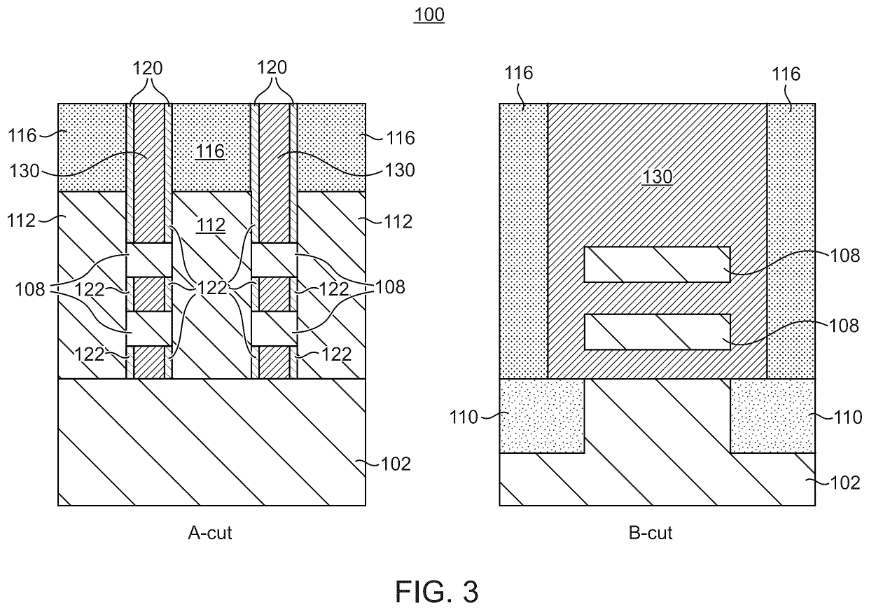

FIG. 2 depicts a partial top-down structure view of a semiconductor IC device 100 and establishes an illustrative cross-sectional planes A-cut and B-cut, for the views of the semiconductor IC device 100. The A-cut cross-sectional plane is through a bottom active region and/or top active region (collectively or individual shown as active region 101) and across gate structures 107. The B-cut cross-sectional plane is through the bottom active region 101 and through one gate structure 107. For clarity, the partial top-down structure views of the semiconductor IC device(s) that establish the A-cut and B-cut cross-sectional planes are repeated in FIG. 3 through FIG. 12, the description(s) of which are not repeated herein.

FIG. 3 depicts an initial fabrication structure cross-section view of an illustrative semiconductor IC device 100, according to one or more embodiments of the disclosure. For clarity, the fabrication of the semiconductor IC device 100 at the present stage may utilize processes that may now be known or that may be developed in the future. For illustration purposes, a particular fabrication process to form semiconductor IC device 100 at the present stage is presented below. This illustrative methodology may be one of many that may achieve or result in the initial semiconductor IC device 100, as depicted. When components referenced in the illustrative methodology below are depicted in FIG. 3, such associated component numeral is expressly utilized. Otherwise, when components are referenced in the illustrative methodology that are not depicted in FIG. 3, a component numeral is not denoted.

The illustrative semiconductor IC device 100 may be formed by initially providing or forming a substrate structure 102. The substrate structure 102 may be a bulk-semiconductor substrate. In one example, the bulk-semiconductor substrate may be a silicon-containing material. In the depicted implementation, the substrate structure 102 includes a top substrate, a lower substrate, and an etch stop layer between the top substrate and the lower substrate. The top substrate and the lower substrate may be comprised of any suitable silicon-containing material(s), and the etch stop layer may be a dielectric material with etch selectivity to one or both top substrate and/or the lower substrate. In one example, the etch stop layer may be an oxide and the substrate structure 102 may be referred to as a buried oxide (BOX) substrate. In a particular example, the lower substrate may be composed of silicon. The etch stop layer may be composed of Silicon Germanium (SiGe) and may be epitaxially grown from the top surface of lower substrate and the top substrate may be composed of Si and may be epitaxially grown from the top surface of etch stop layer.

The illustrative semiconductor IC device 100 may be formed by forming nanolayers over the substrate structure 102 by forming a bottommost sacrificial nanolayer (not shown) and by forming a series of alternating sacrificial nanolayers (not shown) and active nanolayers 108 thereupon. In an implementation, the alternating active sacrificial nanolayer and active nanolayer 108 may be formed by epitaxially growing each layer until the desired number and desired thicknesses of the layers are achieved. Any number of alternating nanolayers can be provided. Epitaxial materials can be grown from gaseous or liquid precursors. For example, epitaxial materials can be grown using vapor-phase epitaxy (VPE), molecular-beam epitaxy (MBE), liquid-phase epitaxy (LPE), or other suitable processes.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases are controlled and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed. For example, an epitaxially grown semiconductor material deposited on a (100) orientated crystalline surface will take on a (100) orientation. In some embodiments, epitaxial growth and/or deposition processes are selective to forming on semiconductor surfaces, and generally do not deposit material on exposed surfaces, such as silicon dioxide or silicon nitride surfaces.

Although it is specifically contemplated that the bottommost sacrificial nanolayer and the sacrificial nanolayers can be formed from SiGe and that the active nanolayers 108 can be formed from Si, it should be understood that any appropriate materials can be used instead, as long as the semiconductor materials have etch selectivity with respect to one or more of the others, as is consistent with the description of the fabrication stages herein.

Although it is specifically contemplated that the bottommost sacrificial nanolayer, the sacrificial nanolayers, and the active nanolayers 108 are formed by epitaxial growth, such nanolayers can be formed by any appropriate mechanism, such as chemical vapor deposition (CVD), physical vapor deposition (PVD), atomic layer deposition (ALD), or gas cluster ion beam (GCIB) deposition, or the like.

The nanolayers may be patterned into nanolayer rows and shallow trench isolation (STI) regions (not shown) may be formed. To form the nanolayer rows, a mask layer may be formed on the topmost nanolayer. The mask layer may be comprised of any suitable mask material(s). Utilizing photolithography and etching techniques, the mask layer may be patterned and used to perform the nanolayer stack patterning process. In the nanolayer stack patterning process, any suitable material removal process (e.g., reactive ion etching or RIE) may be used to remove portions of the alternating nanolayers down to the level of the substrate structure 102, or the like. Following the nanolayer stack patterning process, the one or more nanolayer rows are formed and the mask layer may be removed.

The removal of undesired portion(s) of the alternating nanolayers may further remove undesired portions of substrate structure 102 that are adjacent to respective footprints of nanolayer rows to form STI region openings. The etch may be timed or otherwise controlled to stop the removal of the substrate structure 102 such that the depth or bottom of the one or more STI region openings has a predetermined or desired dimension. For example, the depth or bottom of the one or more STI region openings may be above the etch stop layer, as depicted. In some examples, the etch to form the nanolayer rows may utilize the etch stop layer to stop the etch and form the bottom well of the one or more STI region openings.

A STI region 110 may be formed upon and/or within the substrate structure 102 within respective STI region openings. The STI regions 110 may be formed by depositing electrical dielectric material(s) within respective STI region opening(s) that are adjacent to the one or more nanolayer rows. A top surface of the one or more STI regions 110 may be initially coplanar with or below a top surface of the substrate structure 102. In some implementations, further fabrication operations may generally remove portions of the STI regions 110 (e.g., sacrificial gate removal, replacement gate fabrication pre-clean, etc.), such that the top surfaces of the STI regions 110 are below the top surface of the substrate structure 102.

The one or more STI regions 110 may have a volume and/or geometry that sufficiently electrically isolates components or features of neighboring bottom transistors, or the like, may sufficiently electrically isolate neighboring nanolayer rows.

In an example, the STI regions 110 may be formed by depositing a STI liner within the STI region openings. Subsequently, STI regions 110 may be further formed by depositing STI dielectric material upon the STI liner. A etch back, recess, or the like, may occur to remove undesired or over formed STI liner and/or STI dielectric material, such that the top surface of the STI regions 110 are coplanar with or below a bottom surface of the bottommost sacrificial nanolayer. STI liner may be composed of but not limited to a nitride, low-κ nitride (e.g., a nitride material with a lower dielectric constant relative to SiO₂), or the like. The STI dielectric material may be composed of but not limited to an oxide, low-κ oxide (e.g., an oxide material with a lower dielectric constant relative to SiO₂), or the like.

The illustrated semiconductor IC device 100 may be further fabricated by forming sacrificial gate structures (not shown). The one or more sacrificial gate structures may be formed by patterning a gate cap layer, sacrificial gate layer, and sacrificial gate liner that are formed upon the nanolayers and STI regions 110 by, for example, using lithography and etch processes to remove undesired portions and retain desired portion(s), respectively. The retained desired portion(s) of the gate cap layer, sacrificial gate layer, and sacrificial gate liner may form a sacrificial gate liner, a sacrificial gate, and a sacrificial gate cap, respectively, of each of the one or more sacrificial gate structures. One or more sacrificial gate structures can be formed on targeted regions or areas of semiconductor IC device 100 to define the length of one or more GAA FETs and to provide sacrificial material for yielding targeted GAA FET structure(s) in subsequent processing.

The semiconductor IC device 100 may be further fabricated by forming gate spacers 120 upon the sidewall(s) of the sacrificial gate structures, upon the STI regions 110, and around the one or more nanolayer rows. The semiconductor IC device 100 may be further fabricated by next forming source/drain (S/D) recesses within the one or more nanolayer rows between gate spacers of neighboring sacrificial gate structures. In other words, a single nanolayer row may be separated, by one or more S/D recesses, into multiple nanolayer stacks each located underneath at a portion of respective sacrificial gate structure and associated gate spacer 120. The undesired portions of sacrificial nanolayers, active nanolayers 108, and the like, may be removed by etching or other subtractive removal techniques. As the gate spacers 120 and the sacrificial gate structures may be utilized to protect the underlying portions of sacrificial nanolayers and active nanolayers 108, respective sidewalls of the nanolayer rows may be substantially coplanar and substantially vertical with the outer sidewalls of the gate spacers 120 there above.

As used herein, “substantially vertical” sidewalls deviate from a direction normal to a major surface (e.g., top surface, etc.) of the substrate structure by less than 5°, e.g., 0°, 1°, 2°, 3°, 4°, or 5°, including ranges between any of the foregoing values.

The illustrated semiconductor IC device 100 may be further fabricated by forming horizontal or lateral indents by laterally or horizontally removing respective portions of sacrificial nanolayers within the nanolayer stacks. The indents may be formed by a reactive ion etch (RIE) process, which can remove portions of the sacrificial nanolayers. The illustrated semiconductor IC device 100 may be further fabricated by forming a respective inner spacer 122 within each indent. The one or more inner spacers 122 can be formed by ALD or CVD or any other suitable deposition technique that deposits a dielectric material within the indent(s), thereby forming the inner spacer(s) 122. In some examples, the inner spacers 122 are composed of a low-κ dielectric material (a material with a lower dielectric constant relative to SiO₂), SiN, SiO, SiBCN, SiOCN, SiCO, etc. or any other suitable dielectric material. In certain implementations, after the formation of the inner spacers 122, an isotropic etch process is performed to create substantially vertical sidewalls of the inner spacer(s) 122 that are coplanar with the substantially vertical sidewalls of the active nanolayers 108, of the gate spacers 120, and/or of the bottom isolation.

The illustrated semiconductor IC device 100 may be further fabricated by forming a respective S/D region 112. Each S/D region 112 may form either a source or a drain, respectively, of respective bottom transistors of the stacked transistor, and is connected to respective end surface of the active nanolayers 108 of a nanolayer stack. Each S/D region 112 is composed of a semiconductor material and a dopant. As used herein, a “source/drain” region can be a source region or a drain region depending on subsequent wiring and application of voltages during operation of the applicable transistor. The semiconductor material that provides each of the S/D regions 112 may be composed of one of the semiconductor materials mentioned above for the semiconductor structure. For example, the semiconductor material that provides the S/D region 112 can be compositionally the same, or compositionally different from each active nanolayer 108. The dopant that is present in the S/D region 112 can be either a p-type dopant or an n-type dopant. The term “p-type” refers to the addition of impurities to an intrinsic semiconductor that creates deficiencies of valence electrons, and “n-type” refers to the addition of impurities that contributes free electrons to an intrinsic semiconductor.

The one or more S/D regions 112 may be epitaxially grown or formed. In some examples, the S/D region 112 are formed by in-situ doped epitaxial growth or an ex-situ process may be employed to introduce dopants into the S/D regions 112. Other doping techniques can be used to incorporate dopants in the S/D regions 112.

In some examples, the epitaxial growth that forms the S/D region 112 occurs or is promoted from the top surface of substrate structure 102, from the end surfaces of the active nanolayers 108, or the like, while epitaxial growth may be limited or does not occur from neighboring STI regions 110.

The illustrated semiconductor IC device 100 may be further fabricated by next forming interlayer dielectric (ILD) 116. For example, a blanket ILD 116 may be deposited over the S/D region(s) 112, over the STI regions 110, over the sacrificial gate structures, and over the gate spacers 120, and the like.

The ILD 116 can be any suitable material, such as, for example, porous silicates, carbon doped oxides, silicon dioxides, silicon nitrides, silicon oxynitrides, OPL, or other dielectric materials. In an example, the ILD 116 may be formed to a thickness above the top surface of the sacrificial gate structures. Subsequently, a planarization process, such as a CMP, may be performed to remove excess ILD 116 material and to remove the sacrificial gate caps of the sacrificial gate structures, thereby exposing the sacrificial gate thereunder. The planarization may also partially remove some of the sacrificial gates or may at least expose the sacrificial gate of the sacrificial gate structures.

The illustrated semiconductor IC device 100 may be further fabricated by removing the sacrificial gate structures and releasing the active nanolayers 108 within the nanolayer stacks. The sacrificial nanolayers may be removed by a removal technique, such as one or more series of etches. For example, the etching can include a wet chemical etching process in which one or more chemical etchants are used to remove the sacrificial nanolayers.

The illustrated semiconductor IC device 100 may be further fabricated by forming a replacement gate structure 130 in place of the removed sacrificial gate structures around the active nanolayers 108, upon STI regions 110, etc. Replacement gate structures 130 may be formed by initially forming an interfacial layer on the gate spacers, on the active nanolayers 108, on the bottom isolation, on the inner spacers, etc. that are interior to and/or upon the respective surfaces interior to the opening created by the removal of the sacrificial gate structure and the releasing of the active nanolayers 108. The interfacial layer can be deposited by any suitable techniques, such as ALD, CVD, PVD, thermal oxidation, combinations thereof, or other suitable techniques.

Replacement gate structures 130 may be further formed by forming a high-κ layer to cover the exposed surfaces of the interfacial layer. The high-κ layer can be deposited by any suitable techniques, such as ALD, CVD, metal-organic CVD (MOCVD), PVD, thermal oxidation, combinations thereof, or other suitable techniques. A high-κ material is a material with a higher dielectric constant than that of SiO₂. The replacement gate structures 130 may be further formed by depositing a work function (WF) gate upon the high-κ layer. The WF gate sets the threshold voltage (Vt) of the device. The high-κ layer may separate the WF gate from the nanolayer channel (e.g., active nanolayer 108). Other metals that may be desired to further fine tune the effective work function (eWF) and/or to achieve a desired resistance value associated with current flow through the gate in the direction parallel to the plane of the nanolayer channel.

The one or more replacement gate structures 130 may be further formed by depositing a conductive gate. In an example, when none of the previous replacement gate material(s) are utilized in the replacement gate structures 130, the conductive gate may be formed upon the same or similar surfaces as those upon which the interfacial layer, described above, may be formed. In other examples, when one or more of the interfacial layer, the high-κ layer, the WF gate, or the like, are utilized in the replacement gate structures, the conductive gate may be formed upon the most recent structural formation thereof. The conductive gate can be comprised of a conductor material and/or metal, such as but not limited to, e.g., tungsten, aluminum, ruthenium, rhodium, cobalt, copper, tantalum, titanium, or the like. After the replacement gate structure 130 formation, the top surface of the semiconductor IC device 100 may be planarized by a planarization technique such as a CMP, mechanical grinding process, or the like.

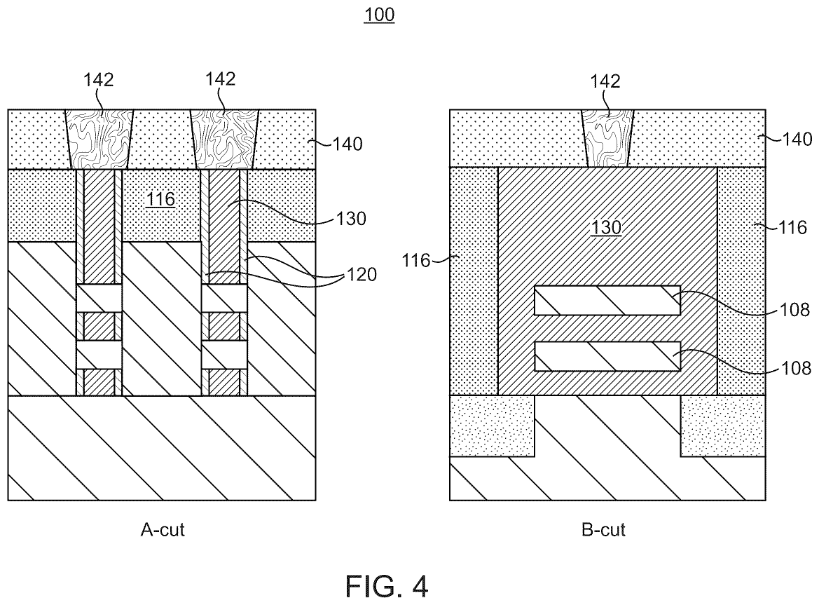

FIG. 4 depicts cross-sectional views of a semiconductor IC device 100 shown after representative fabrication operation(s), in accordance with one or more embodiments. In the depicted fabrication stage, a bonding layer 140 may be formed and a respective gate-to-gate contact 142 may be formed within the bonding layer 140 upon a respective replacement gate structure 130.

The bonding layer 140 may consist of one or more dielectric bonding material(s), such as an oxide, nitride, or the like, and may be formed by ALD or CVD or any other suitable deposition technique that deposits a dielectric material. In some examples, the bonding layer 140 are composed of a dielectric material that has adequate etch selectivity to the material of ILD 116, gate spacers 120, and/or replacement gate structure 130. In some examples, the bonding layer 140 may be deposited as a blanket layer upon a frontside or top surface of the semiconductor IC device 100.

The gate-to-gate contacts 142 may be formed by patterning respective openings (e.g., in the prior, same, or subsequent masking stage) within the bonding layer 140 from the frontside of the semiconductor IC device 100. As such a diameter of the gate-to-gate contact 142 at its top surface may be greater than a diameter at its bottom surface. The opening may expose at least a portion of the underlying replacement gate structure 130. The opening may be inset, partially inset, or entirely outside of the underlying active nanolayers 108. The opening may expose at least a portion of the gate spacer 120 that surrounds the associated exposed replacement gate structure 130. The opening may be a circular, elliptical, polygonal, or the like, well, as viewed from the frontside of the semiconductor IC device 100.

The gate-to-gate contacts 142 may be formed by depositing conductive material such as metal into the respective gate-to-gate contact openings. In an example, gate-to-gate contacts 142 may be formed by depositing a liner, such as Ni, NiPt or Ti, etc. into the opening(s), depositing an adhesion liner, such as TiN, TaN, etc. upon the liner, and by depositing a conductive fill, such as Al, Ru, W, Co, Cu, etc. upon the metal adhesion liner. Subsequently, a planarization process, such as a CMP process or a mechanical grinding process, may remove excess portions of the liner, the metal adhesion liner, the conductive fill, and the bonding layer 140. Therefore, the top surface of the gate-to-gate contacts 142 and the bonding layer 140 may be coplanar.

Each gate-to-gate contact 142 may be in direct, indirect, and/or electrical contact with underlying replacement gate structure 130. For example, a particular gate-to-gate contact 142 may be directly connected to a top surface of the replacement gate structure 130 that is exposed by the associated gate-to-gate contact opening. In an embodiment, the conductive material of the gate-to-gate contact 142 may be substantially the same as the conductive material(s) of the underlying replacement gate contact. In an alternative embodiment, the conductive material of the gate-to-gate contact 142 may be different relative to the conductive material(s) of the underlying replacement gate contact 130.

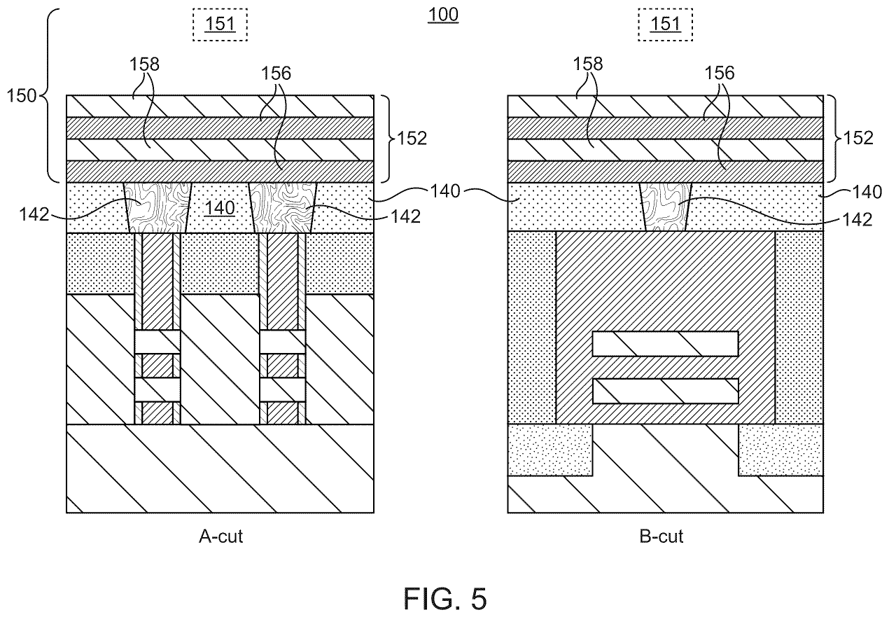

FIG. 5 depicts cross-sectional views of a semiconductor IC device 100 shown after representative fabrication operation(s), in accordance with one or more embodiments. In the depicted fabrication stage, top transistor nanolayers 152 may be bonded to the frontside of the semiconductor IC device 100.

For example, semiconductor IC device 150 which may include top transistor nanolayers 152 and a substrate 151 may be bonded to the frontside of the semiconductor IC device 100. The top transistor nanolayers 152 may include alternating active nanolayers 158 and sacrificial nanolayers 156. In the example illustrated, there are a total of two sacrificial nanolayers 156 and two active nanolayers 158 that are alternately formed to create the top transistor nanolayers 152. However, it should be appreciated that any suitable number of alternating layers may be formed. Although it is specifically contemplated that the sacrificial nanolayers 156 can be epitaxially formed from SiGe and that the active nanolayers 158 can be formed from Si, it should be understood that any appropriate materials and formation techniques can be used instead, as long as the two semiconductor materials have etch selectivity with respect to one another.

In certain embodiments, the sacrificial nanolayers 156 have a vertical thickness ranging, for example, from approximately 3 nm to approximately 20 nm. In certain embodiments, the active nanolayers 158 have a vertical thickness ranging, for example, from approximately 3 nm to approximately 10 nm. Although the range of 3-20 nm is cited as an example range of thickness, other thickness of these layers may be used. In certain examples, certain of the sacrificial nanolayers or the active nanolayers 158 may have different thicknesses relative to one another. Therefore, multiple epitaxial growth processes can be performed to form the alternating top transistor nanolayers 152.

In certain embodiments, it may be desirable to have a VSP between adjacent top transistor nanolayers 152 to reduce the parasitic capacitance and to improve circuit speed. For example, the VSP (the distance between adjacent active nanolayers 158) may range from 5 nm to 15 nm. However, the VSP should be of sufficient value to accommodate the replacement gate that will be formed in the spaces created by later removal of respective portions of the sacrificial nanolayers. In some cases, the vertical thickness of the active nanolayers 158 and/or spacing between the active nanolayers are the same or different relative to the associated dimensions of the active nanolayers 108.

In the embodiments, the substrate 151 may be removed and the top transistor nanolayers 152 may be retained and otherwise associated with the semiconductor IC device 100 by the bonding layer 140. The substrate 151 may be removed by any known removal process, such as an etch, a CMP, or the like.

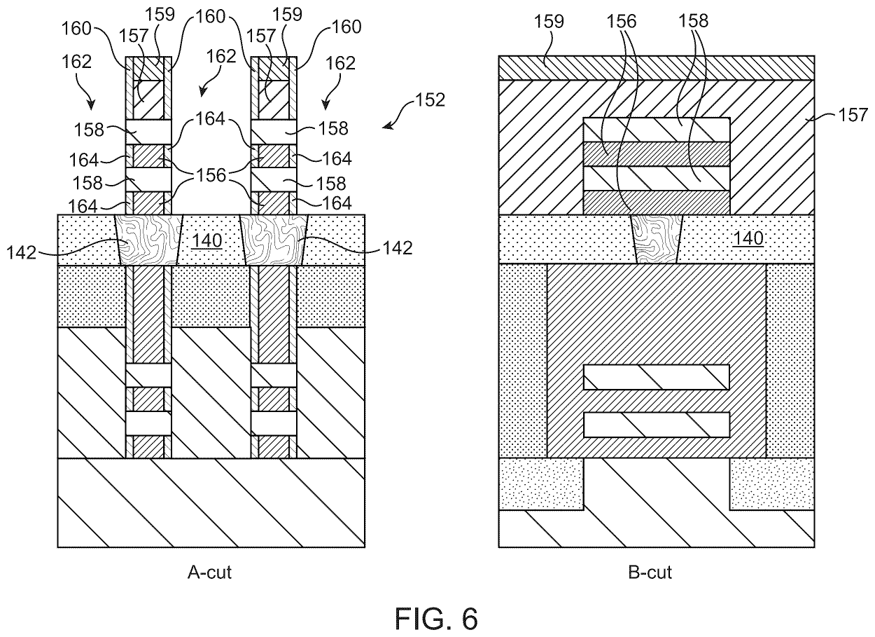

FIG. 6 depicts cross-sectional views of semiconductor IC device 100 shown after representative fabrication operation(s), in accordance with one or more embodiments. In the depicted stages, the top transistor nanolayers 152 may be patterned, top sacrificial gate structures may be formed, top gate spacers 160 may be formed, top source/drain (S/D) canyons 162 may be formed, and inner spacers 164 may be formed.

For example, the top transistor nanolayers 152 may be patterned into nanolayer rows. To form one or more nanolayer rows, a mask layer (not shown) may be formed on the topmost nanolayer of the top transistor nanolayers 152. The mask layer may be comprised of any suitable mask material(s). The mask layer may be patterned and used to perform the nanolayer row patterning process. In the nanolayer row patterning process, any suitable material removal process (e.g., reactive ion etching or RIE) may be used to remove portions of the alternating top transistor nanolayers 152 down to the level of the bonding layer 140. Following the nanolayer row patterning process, one or more nanolayer rows are formed. Subsequently, the mask layer may be removed.

Semiconductor IC device 100 may be further formed by forming sacrificial gate structures over the nanolayer rows. The one or more top sacrificial gate structures may include a top sacrificial gate liner (not shown), a top sacrificial gate 157, and a top sacrificial gate cap 159. The top sacrificial gate structures may be formed by initially depositing a top sacrificial gate liner layer (e.g., a dielectric, oxide, or the like) upon the bonding layer 140 and upon and around the one or more nanolayer rows. The top sacrificial gate structures may further be formed by subsequently depositing a top sacrificial gate layer (e.g., amorphous silicon, or the like) upon the top sacrificial gate liner layer. The thickness of the top sacrificial gate layer may be such that the top surface of the top sacrificial gate layer is above the top surface of the one or more nanolayer rows. The top sacrificial gate structures may further be formed by forming a gate cap layer upon the top sacrificial gate layer. The gate cap layer may be formed by depositing a mask material, such as a hard mask material, such as silicon nitride, silicon oxide, combinations thereof, or the like, upon the top sacrificial gate layer. The gate cap layer may be composed of one or more layers of masking materials to protect the top sacrificial gate layer and/or other underlying materials during subsequent processing of semiconductor IC device 100.

The one or more top sacrificial gate structures may further be formed by patterning the gate cap layer, top sacrificial gate layer, and top sacrificial gate liner by, for example, using lithography and etch processes to remove undesired portions and retain desired portion(s), respectively. The retained portion(s) of the gate cap layer, top sacrificial gate layer, and top sacrificial gate liner may form the top sacrificial gate liner (not shown), the top sacrificial 158, and the top sacrificial gate cap 159, respectively, of each of the one or more top sacrificial gate structures.

One or more top sacrificial gate structures can be formed on targeted regions or areas of semiconductor IC device 100 to define the gate length of one or more top transistors and to provide sacrificial material for yielding targeted top transistor structure(s) in subsequent processing. In embodiments, a respective top sacrificial gate structure may be formed in line with a particular lower sacrificial gate structure. For clarity, respective top sacrificial gate structures may be formed in line with or off-set from a bottom replacement gate structure 130.

Further in the depicted fabrication stages, top gate spacers 160 may be formed. The top gate spacers 160 may be formed upon the sidewall(s) of the top sacrificial gate structures, upon the bonding layer 140, and around the one or more nanolayer rows. The top gate spacers 160 may be formed by a conformal deposition of a dielectric material, such as silicon nitride, SiBCN, SiNC, SiN, SiCO, SiNOC, or a combination thereof, or the like, upon bonding layer 140, upon and around the one or more top sacrificial gate structures, and upon and around the one or more nanolayer rows. Subsequently, undesired portions of dielectric material may be removed while desired portions the dielectric material may be retained and thereby form the top gate spacer(s) 160. The undesired portions of dielectric material may be removed by a directional ion etch, such as a reactive ion etch (RIE).

Further in the depicted fabrication stages, top source/drain (S/D) canyons 162 may be formed within the one or more nanolayer rows between top gate spacers 160 of neighboring top sacrificial gate structures. In other words, a single nanolayer row may be separated, by a top S/D canyon 162, into multiple nanolayer stacks, each located underneath a respective top sacrificial gate structure. The one or more top S/D canyons 162 may be formed between adjacent top sacrificial gate structures by removing respective portions of the top transistor nanolayers, that are between top gate spacers of adjacent or neighboring top sacrificial gate structures. The one or more top S/D canyons 162 may be formed to a depth to stop at the top surface of the bonding layer 140, or the like. The undesired portions of top transistor nanolayers may be removed by etching or other subtractive removal techniques. The top surface of the bonding layer 140 may be used as an etch stop or other etch parameters may be controlled to stop the material removal at the bonding layer 140. As the top gate spacers 160 and the top sacrificial gate structures may be utilized to protect the underlying portions of top transistor nanolayers, respective sidewalls of the nanolayer stacks may be substantially coplanar and/or substantially vertical with the outer sidewalls of the top gate spacers 160, there above.

Further in the depicted fabrication stages, sacrificial nanolayers 156 may be indented and a respective top inner spacer 164 may be formed in each indent. For example, horizontal or lateral indents may be formed by laterally or horizontally (e.g., into and/or out of the page of the depicted B-cut cross-section) removing respective portions of sacrificial nanolayers 156 within the nanolayer stacks. The indents may be formed by a reactive ion etch (RIE) process, which can remove portions of the sacrificial nanolayers 156. The horizontal depth of the indents may be chosen to set a length for a replacement gate structure that is formed in place of one top sacrificial gate structure. When the sacrificial nanolayers 156 are composed of SiGe and when active nanolayers 158 are Si, the directional RIE can use a boron-based chemistry or a chlorine-based chemistry, for example, which recesses or removes the exposed end portions of sacrificial nanolayers 156 (e.g., end portions of sacrificial nanolayers 156 generally below the gate spacer) selective to the Si active nanolayers 158. In alternative implementations when sacrificial nanolayers 156 are not SiGe and when active nanolayers 158 are not Si, the directional etch of the sacrificial nanolayers 156 may generally be selective to the active nanolayers 158, top gate spacers 160, and/or bonding layer 140.

Further in the depicted fabrication stages, a respective top inner spacer 164 may be formed within each indent. The one or more top inner spacers 164 can be formed by ALD or CVD or any other suitable deposition technique that deposits a dielectric material within the indent(s), thereby forming the top inner spacer(s). In some examples, the top inner spacers 164 are composed of a low-κ dielectric material, SiN, SiO, SiBCN, SiOCN, SiCO, etc. or any other suitable dielectric material. In certain implementations, after the formation of the top inner spacer 164, an isotropic etch process is performed to create substantially vertical sidewalls of the top inner spacer 164 that are coplanar with the substantially vertical sidewalls of the active nanolayers 158, of the top gate spacers 160, or the like.

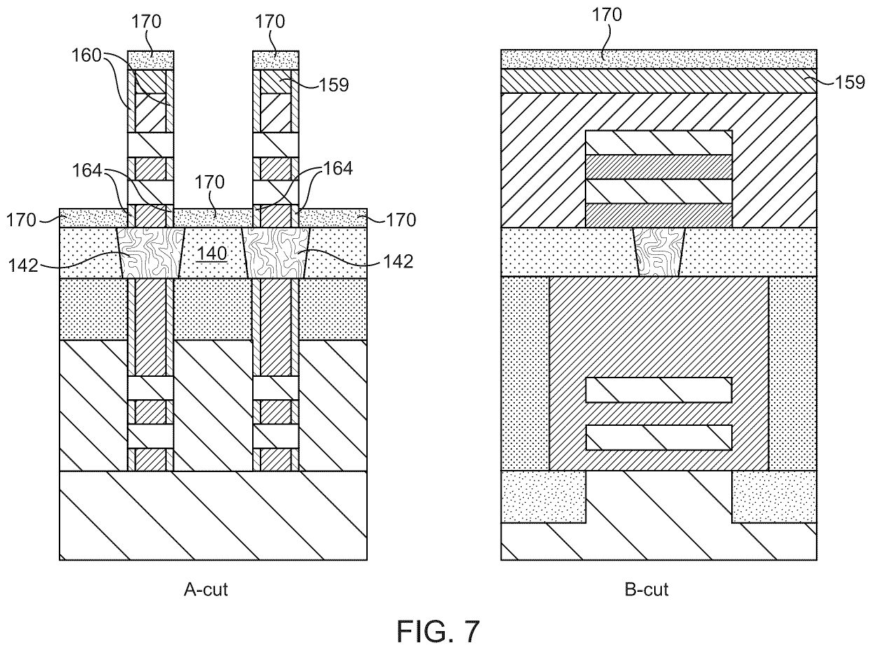

FIG. 7 depicts cross-sectional views of semiconductor IC device 100 shown after representative fabrication operation(s), in accordance with one or more embodiments. In the depicted stage, bonding layer spacer 170 may be formed.

The bonding layer spacer 170 may be respectively formed upon the bonding layer 140, upon the gate-to-gate contacts 142, and upon and the bottom most inner spacers 164. In one example, bonding layer spacer 170 may be formed of a dielectric material(s), such as such as silicon nitride, SiBCN, SiNC, SiN, SiCO, SiNOC, a combination thereof, or the like.

The bonding layer spacer 170 may be formed by a deposition of a blanket gate spacer dielectric material. Excess, undesired, and/or exposed blanket gate spacer dielectric material may be subsequently removed by a substrative removal technique, such as an etch. For example, a directional etch may remove exposed vertical portion(s) of the blanket gate spacer dielectric material while leaving the horizontal portion(s) of the bonding layer 140, upon the gate-to-gate contacts 142, and upon and the bottom most inner spacers 164. In some examples, bonding layer spacer 170 may further remain upon the top surface of the gate spacers 160 and upon the top surface of the sacrificial gate cap 159.

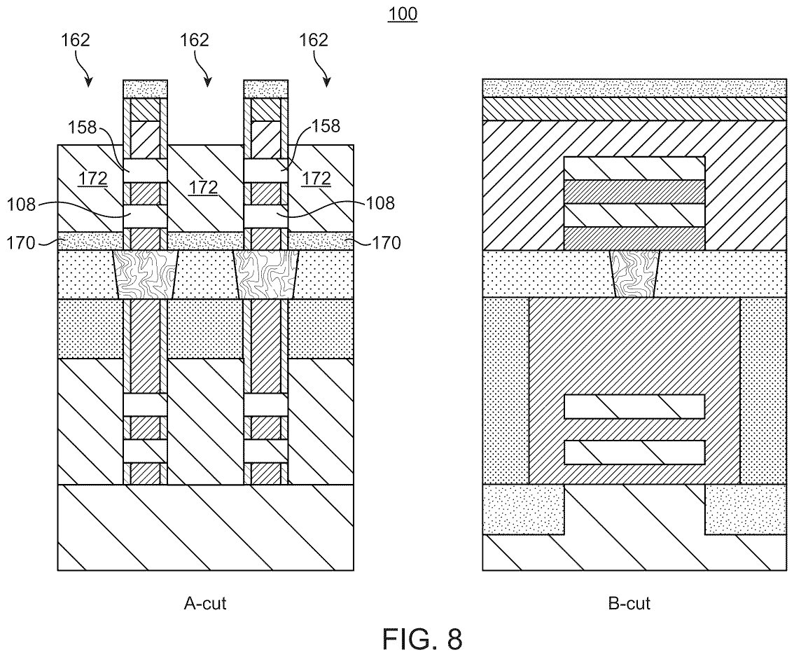

FIG. 8 depicts cross-sectional views of semiconductor IC device 100 shown after representative fabrication operation(s), in accordance with one or more embodiments. In the depicted stage, top S/D regions 172 may be formed.

The top S/D region 172 may be formed within each S/D canyon 162. The top S/D region 172 forms either a source or a drain, respectively, of respective top transistor, such as a GAA FET, and is connected to respective a side or end surface of the active nanolayers 158 of adjacent top nanolayer stacks. The top S/D region 172 may be composed of a semiconductor material and a dopant. The semiconductor material that provides each top S/D region 172 may be composed of one of the semiconductor materials mentioned above for the semiconductor structure. The semiconductor material that provides the top S/D region 172 can be compositionally the same, or compositionally different from each active nanolayers 158. The dopant that is present in the top S/D region 172 can be either a p-type dopant or an n-type dopant.

The one or more top S/D regions 172 may be epitaxially grown or formed from the exposed end surfaces of the active nanolayers 158), while epitaxial growth is limited or does not occur from the bonding layer spacer 170. In some examples, the top S/D regions 172 may be formed by in-situ doped epitaxial growth. The use of an in-situ doping process is merely an example. For instance, one may instead employ an ex-situ process to introduce dopants into the source and drains. Other doping techniques can be used to incorporate dopants in the top source/drain region 172. Dopant techniques include but are not limited to, ion implantation, gas phase doping, plasma doping, plasma immersion ion implantation, cluster doping, infusion doping, liquid phase doping, solid phase doping, in-situ epitaxy growth, or any suitable combination of those techniques. In examples, the S/D epitaxial growth conditions that promote in-situ Boron doped SiGe for p-type transistor and phosphorus or arsenic doped silicon or Si:C for n-type transistors.

In some embodiments, epitaxial growth to form the one or more top S/D regions 172 may overgrow above the top surface of the top sacrificial gate structure(s) and be subsequently recessed such that the top surface of the top S/D region 172 may be substantially horizontal and above the top surface of the topmost active nanolayer 158 within the nanolayer stacks (e.g., to enable contact between this active nanolayer 158 and the top S/D region 172).

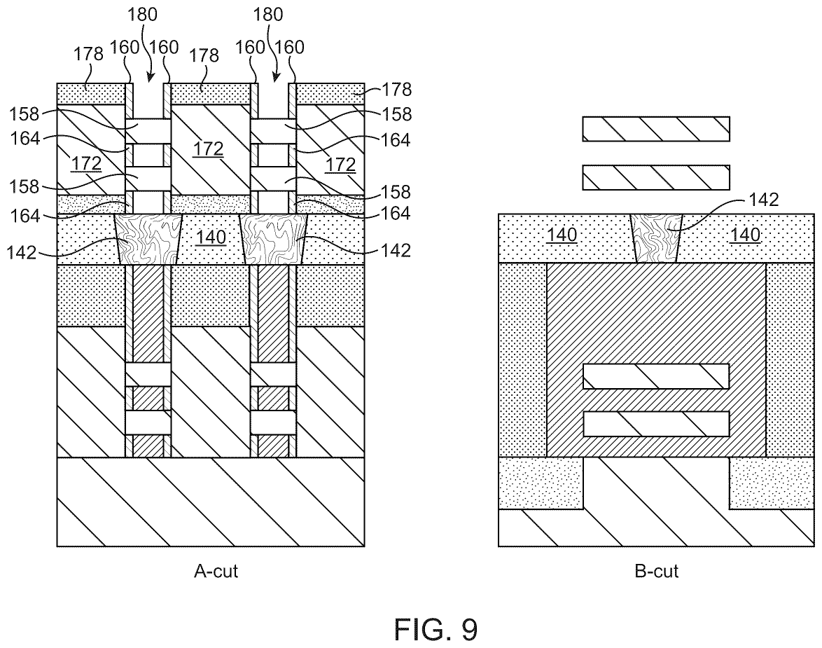

FIG. 9 depicts cross-sectional views of semiconductor IC device 100 shown after representative fabrication operation(s), in accordance with one or more embodiments. In the depicted stage, top ILD 178 may be formed, the sacrificial gate structures may be removed, and the active nanolayers 158 may be released.

The top ILD 178 may be formed. For example, a blanket top ILD 178 material may be deposited over the top S/D region(s) 172, upon the bonding layer 140, over the top sacrificial gate structures, and over the top gate spacers 160.

The top ILD 178 can be any suitable material, such as, for example, porous silicates, carbon doped oxides, silicon dioxides, silicon nitrides, silicon oxynitrides, OPL, or other dielectric materials. Any known manner of forming the top ILD 178 can be utilized. The top ILD 178 can be formed using, for example, CVD, PECVD, ALD, flowable CVD, spin-on dielectrics, or PVD.

In an example, the top ILD 178 may be formed to a thickness above the top surface of the top sacrificial gate structures. Subsequently, a planarization process, such as a CMP, may be performed to remove excess top ILD 178 material and to remove the top sacrificial gate caps 159 of the top sacrificial gate structures, thereby exposing the top sacrificial gate 157 thereunder. The planarization may also partially remove some of the top sacrificial gates 157 or may at least expose the top sacrificial gate 157. The CMP may create a substantially planar or substantially horizontal top surface for the semiconductor IC device 100. In other words, the respective top surfaces of the top ILD 178, top gate spacers 160, top sacrificial gates 157, etc. may be substantially coplanar and/or substantially horizontal.

Further, in the depicted fabrication stage(s), the top sacrificial gate structures may be removed which may form a replacement gate structure opening 180. The top sacrificial gate structures may be removed by a selective etch of the top sacrificial gate 157 In a particular embodiment, the removal of the sacrificial gate structures may further remove the sacrificial nanolayers 156. Therefore, void spaces may exist between the retained active semiconductor nanolayers 158. Consequently, the active semiconductor nanolayers 158 may be referred to as released. It should be appreciated that during the removal of the sacrificial gate structures appropriate etchants are used that do not significantly remove material of active semiconductor nanolayers 158, top gate spacers 160, inner spacers 164, gate-to-gate contact 142, bonding layer 140, or the like. For clarity, the replacement gate structure opening 180 may expose at least a portion of a top surface of the associated inline gate-to-gate contact 142.

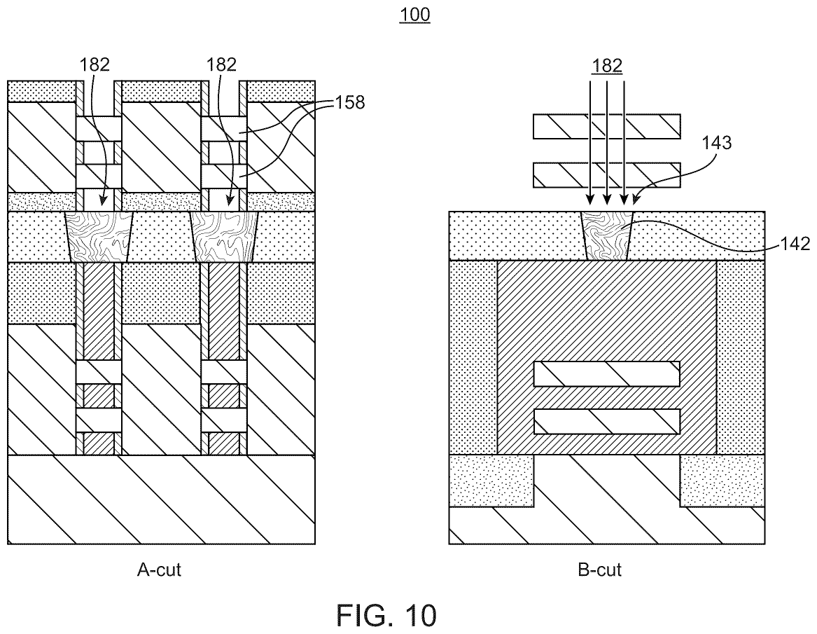

FIG. 10 depicts cross-sectional views of semiconductor IC device 100 shown after representative fabrication operation(s), in accordance with one or more embodiments. In the depicted stage, a surface treatment 182 may be applied to a exposed surface 143 of the gate-to-gate contact 142.

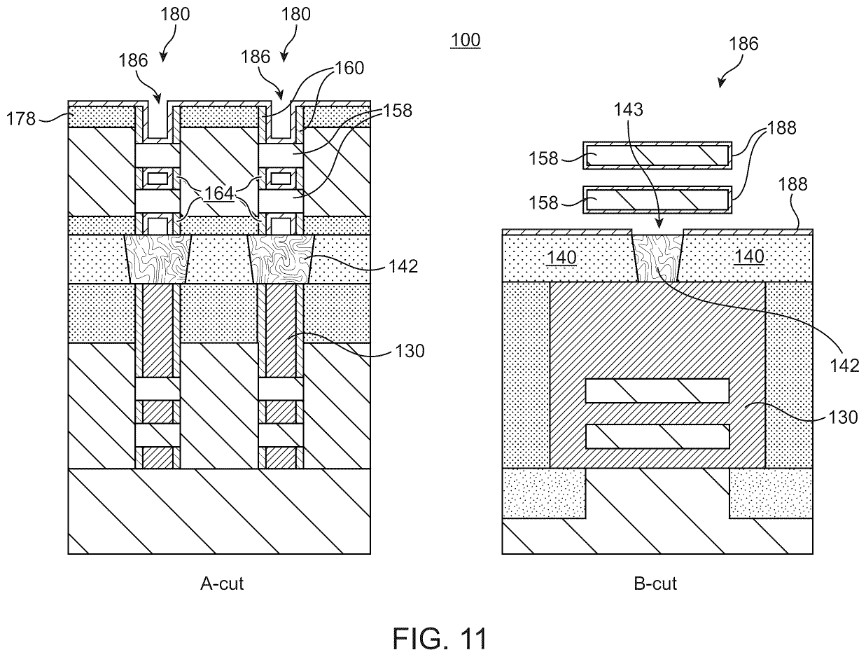

The surface treatment 182 may directed to, local, or associated only with the material(s) of the gate-to-gate contact 142 and may adequately or substantially block or otherwise dimmish the deposition of an a high-κ dielectric material upon the exposed surface 143 of the gate-to-gate contact 142. For example, the surface treatment 182 may not be associated or may not form upon the active nanolayers 158 but may be self-aligned or locally applied to the gate-to-gate contact 142. In a particular example, surface treatment 182 may be a self-assembled monolayer (SAM) selectively applied to the exposed conductive metal surface 143 of the gate-to-gate contact 142 which may subsequently prevent ALD of the interfacial layer and/or a high-κ dielectric layer of the replacement gate structure, as depicted in FIG. 11.

FIG. 11 depicts cross-sectional views of semiconductor IC device 100 shown after representative fabrication operation(s), in accordance with one or more embodiments. In the depicted stage, replacement gate structures 186 are partially formed.

For example, replacement gate structures 186 may be formed in place of the removed upper sacrificial gate structures around one or more active semiconductor nanolayers 158. For clarity, the replacement gate structure 186 may be a distinct gate structure relative to the replacement gate structure 130. In an example, the top replacement gate structure 186 may be in line, or at least partially off-set, with the bottom replacement gate structure 130.

The replacement gate structure 186 may be partially formed by initially forming an interfacial layer (not shown) on the interior surfaces of the replacement gate opening 180. Then, a high-κ layer 188 may be formed to cover the surfaces of exposed surfaces of the interfacial layer. In an example, the interfacial layer is sufficiently thin relative to the high-κ layer 188, which may effectively consume the interfacial layer, such that the high-κ layer 188 may be in direct contact with the interior surfaces of the replacement gate opening 180. For example, high-κ layer 188 may be formed directly upon the ILD 178, upon the gate spacers 160, upon the active nanolayers 158, upon the inner spacers 164, and upon the bonding layer 140. In other examples, the interfacial layer is absent and the high-κ layer 188 may be formed directly upon the ILD 178, upon the gate spacers 160, upon the active nanolayers 158, upon the inner spacers 164, and upon the bonding layer 140.

The high-κ layer can be deposited by any suitable techniques, such as ALD, CVD, metal-organic CVD (MOCVD), physical vapor deposition (PVD), thermal oxidation, combinations thereof, or other suitable techniques. The high-κ dielectric material is a material with a higher dielectric constant than that of SiO₂, and can include e.g., LaO, AlO, ZrO, TiO, Ta₂O₅, Y₂O₃, SrTiO₃(STO), BaTiO₃(BTO), BaZrO, HfZrO, HfLaO, HfSiO, LaSiO, AlSiO, HfTaO, HfTiO, (Ba,Sr)TiO₃(BST), Al₂O₃, Si₃N₄, oxynitrides (SiON), or other suitable materials.

For clarity, for example, due to surface treatment 182, ALD of the interfacial layer and/or a high-κ dielectric layer 188 of the replacement gate structure 186 may be blocked or otherwise not sufficiently deposited upon the exposed surface 143 of the gate-to-gate contact 142.

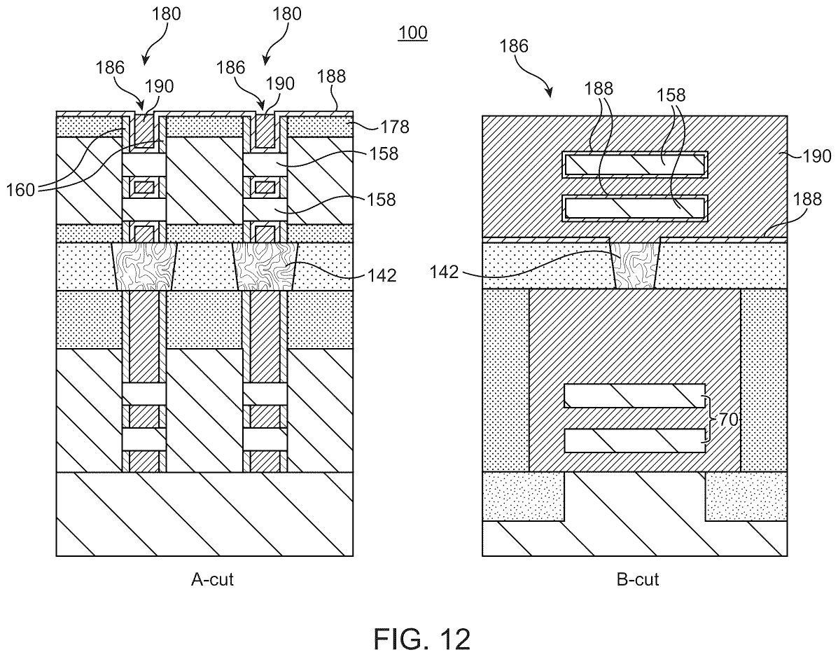

FIG. 12 depicts cross-sectional views of semiconductor IC device 100 shown after representative fabrication operation(s), in accordance with one or more embodiments. In the depicted stage, replacement gate structures 186 are further formed.

The replacement gate structure 186 may be further formed by depositing a work function metal (WFM) gate 190 upon the high-κ layer 188. The WFM gate 190 can be comprised of metals, such as, e.g., copper (Cu), cobalt (Co), aluminum (Al), platinum (Pt), gold (Au), tungsten (W), titanium (Ti), nitride (N) or any combination thereof. The metal can be deposited by a suitable deposition process, for example, chemical vapor deposition (CVD), plasma enhanced chemical vapor deposition (PECVD), physical vapor deposition (PVD), plating, thermal or e-beam evaporation, or sputtering. In various exemplary embodiments, the height of the replacement gate can be reduced by chemical-mechanical polishing (CMP) and/or etching. Therefore, the planarization process can be provided by CMP. Other planarization process can include grinding and polishing. In general, the replacement gate sets the threshold voltage (Vt) of the top transistors and the bottom transistors. The high-κ layer 188 may separate the WFM gate 190 from the active semiconductor nanolayers 158. Other metals that may be desired to further fine tune the effective work function (eWF) and/or to achieve a desired resistance value associated with current flow through the replacement gate structure 186.

If needed, to further fill the replacement gate structure opening 180, a metal fill (not shown) may be formed over the WFM gate 190. The metal layer may include, e.g., Ti, Ag, Al, TiAlN, TaC, TaCN, TaSiN, Mn, Zr, TiN, TaN, Ru, Mo, Al, WN, Cu, W, or any suitable materials. After the replacement gate structure 186 formation, the top surface of the semiconductor IC device 100 may be planarized by a planarization technique such as a CMP, mechanical grinding process, or the like (not shown). Thereafter, the top surface of ILD 178, replacement gate structures 186, gate spacers 160, etc. may be substantially horizontal and/or substantially coplanar.

For clarity, though not shown, semiconductor IC device 100 may undergo further fabrication operations, such as middle of line (MOL) contact formation, frontside back end of line (BEOL) fabrication, and/or backside BEOL fabrication.

Semiconductor IC device 100 may be an integrated circuit (IC) chip. IC chips can be distributed by the fabricator in raw wafer form (that is, as a single wafer that has multiple unpackaged chips), as a bare die, or in a packaged form. In the latter case, the IC chip may mount in a single chip package (such as a plastic carrier, with leads that are affixed to a motherboard or other higher-level carrier) or in a multichip package (such as a ceramic carrier that has either or both surface interconnections or buried interconnections). In any case, the IC chip may be integrated with other chips, discrete circuit elements, and/or other signal processing devices as part of either (a) an intermediate product, such as a motherboard, or (b) an end product. The end product can be any product that includes the IC chip, ranging from toys and other low-end applications to advanced computer products having a display, a keyboard or other input device, and a central processor.

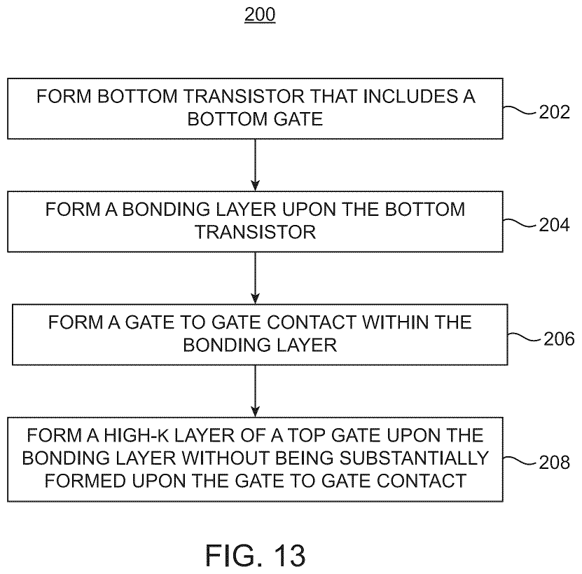

FIG. 13 depicts a flow diagram illustrating a method 200 to fabricate a semiconductor IC device. The depicted fabrication operations of method 200 may be illustratively depicted and described above with reference to one or more of FIG. 3 through FIG. 12 of the drawings, which describe the fabrication of a semiconductor IC device 100 at various stages of fabrication, though various fabrication operations described in method 200 may be used to fabricate other types of semiconductor IC devices. The method 200 depicted herein is illustrative. There can be many variations to the diagram or operations described therein without departing from the spirit of the embodiments. For instance, the operations can be performed in a differing order, or operations can be added, deleted, or modified.

Method 200 may begin, at block 202, with forming a bottom transistor that includes a bottom gate. For example, a bottom transistor may be formed that includes bottom S/D region(s) 112, bottom active nanolayers 108, and/or a bottom replacement gate structure 130. Method 200 may continue, at block 204, with forming a bonding layer upon the bottom transistor. For example, bonding layer 140 may be formed upon one or more of the regions of the bottom transistor. Method 200 may continue, at block 206, with forming a gate-to-gate contact within the bonding layer. For example, gate-to-gate contact 142 is formed within the bonding layer 140. Method 200 may continue, at block 208, with forming a high-κ layer upon the bonding layer without being substantially formed upon the gate-to-gate contact. For example, a surface treatment 182 may be formed upon the gate-to-gate contact 142 that prevents substantial (e.g., less than a predetermined threshold) formation of the high-κ layer 188 upon the gate-to-gate contact 142.

The descriptions of the various embodiments have been presented for purposes of illustration and are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

The descriptions of the various embodiments have been presented for purposes of illustration and are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor integrated circuit (IC) device comprising:
a top transistor comprising a top gate that at least includes a high-κ layer and a gate conductor;
a bottom transistor comprising a bottom gate;
a bonding layer that connects the top transistor to the bottom transistor; and
a gate-to-gate contact within the bonding layer that electrically connects gate conductor to the bottom gate.

2. The semiconductor IC device of claim 1, wherein the bonding layer is directly connected to the high-κ layer and to the bottom gate.

3. The semiconductor IC device of claim 1, wherein the top transistor comprises a top source/drain (S/D) region and a plurality of channels directly connected to the top S/D region and directly connected to the high-κ layer.

4. The semiconductor IC device of claim 3, further comprising:
a dielectric spacer between the gate-to-gate contact and the top S/D region.

5. The semiconductor IC device of claim 4, wherein the dielectric spacer is directly connected to the bonding layer, directly connected to the gate-to-gate contact, and directly connected to the top S/D region.

6. The semiconductor IC device of claim 3, wherein the gate-to-gate contact is laterally inset and below the plurality of channels.

7. The semiconductor IC device of claim 3, wherein the gate-to-gate contact is partially inset and below the plurality of channels.

8. The semiconductor IC device of claim 1, wherein the gate-to-gate contact has a horizontal length that is greater than a gate length of the top gate and a gate length of the bottom gate.

9. The semiconductor IC device of claim 4, wherein a top surface of the dielectric spacer is below a bottom surface of a bottommost channel of the plurality of channels.

10. A semiconductor integrated circuit (IC) device comprising:
a bonding layer;
a gate-to-gate contact within the bonding layer, the gate-to-gate contact extending from a top surface of a bonding layer to a bottom surface of the bonding layer; and
a top gate that comprising a high-κ layer that is directly connected to the bonding layer and a gate conductor that is directly connected to the gate-to-gate contact.

11. The semiconductor IC device of claim 10, further comprising:
a bottom gate that is electrically connected to the gate-to-gate contact.

12. The semiconductor IC device of claim 11, wherein the high-κ layer of the top gate wraps around a plurality of top channels and wherein the bottom gate wraps around a plurality of bottom channels.

13. The semiconductor IC device of claim 12, wherein the gate-to-gate contact is laterally inset and below the plurality of top channels.

14. The semiconductor IC device of claim 12, wherein the gate-to-gate contact is partially inset and below the plurality of top channels.

15. The semiconductor IC device of claim 12, wherein the gate-to-gate contact is laterally inset and above the plurality of bottom channels.

16. The semiconductor IC device of claim 12, wherein the gate-to-gate contact is partially inset and above the plurality of top channels.

17. The semiconductor IC device of claim 12, wherein the gate-to-gate contact has a horizontal length that is greater than a gate length of the top gate.

18. The semiconductor IC device of claim 12, further comprising:
a top source/drain (S/D) region directly connected to the plurality of top channels; and
a dielectric spacer directly between the gate-to-gate contact and the top S/D region.

19. The semiconductor IC device of claim 18, wherein the dielectric spacer is in direct contact with the bonding layer.

20. A semiconductor integrated circuit (IC) device fabrication method comprising:
forming a bottom transistor that includes a bottom gate;
forming a bonding layer upon the bottom transistor;
forming a gate-to-gate contact within the bonding layer and in direct contact with the bottom gate; and
forming a high-κ layer of a top gate upon the bonding layer without being substantially formed upon the gate-to-gate contact.
